(19) United States
(12) Patent Application Publication
(10) Pub. No.: US 2022/0181165 A1
(43) Pub. Date: Jun. 9, 2022

(54) Fabrication Method of Flexible Cyclo-Olefin Polymer (COP) Substrate for IC Packaging of Communication Devices and Biocompatible Sensors Devices

(71) Applicant: Compass Technology Company Limited, Shatin (HK)

(72) Inventors: Kelvin Po Leung Pun, Shatin (HK); Jason Rotanson, Kowloon (HK); Chee Wah Cheung, Kowloon (HK)

(21) Appl. No.: 17/115,085

(22) Filed: Dec. 8, 2020

(51) Int. Cl. H01L 21/48; H01L 23/66; H01L 23/00; H01L 23/498; H01L 23/14; C23C 18/20; C25D 5/56; C23F 17/00; C25D 7/12; H01Q 1/22

(52) U.S. Cl. CPC H01L 21/4846; H01Q 9/0407; H01L 23/66; H01L 24/83; H01L 23/4985; H01L 23/145; H01L 24/16; C23C 18/204; C25D 5/56; C23F 17/00; C25D 7/123; H01Q 1/2283; H01L 2223/6677; H01L 2224/83801; H01L 2224/8385; H01L 2224/16225; H01L 21/4803

(57) ABSTRACT

A method to produce a flexible substrate is described. A base film material of cyclo-olefin polymer (COP) is provided. A surface of the COP base film is irradiated with UV light to form a functional group on the COP surface. Thereafter, the surface is treated with an alkaline degreaser. Thereafter, a Ni—P seed layer is electrolessly plated on the surface. A photoresist pattern is formed on the Ni—P seed layer. Copper traces are plated within the photoresist pattern. The photoresist pattern is removed and the Ni—P seed layer not covered by the copper traces is etched away to complete the flexible substrate. Alternatively, a biocompatible flexible substrate is formed using a Ni—P seed layer with a biocompatible surface finishing instead of copper.

### TECHNICAL FIELD

This application relates to producing a flexible substrate for integrated circuit packaging, and more particularly, to producing a cyclo-olefin polymer flexible substrate for integrated circuit packaging and biocompatible sensors.

### BACKGROUND

With the rapid growth of the 5G network as a telecommunication standard for future devices, electronic devices are expected to operate based on a millimeter scale wave length (mm wave) in the frequency range of 30-300 GHz. Such a system offers a vast amount of bandwidth for high data rates which is particularly attractive for the Internet of Things (IoTs), Advanced Driver Assistance Systems (ADAS), Massive Multiple-Input Multiple-Output (MIMO), and the like. To enable these applications, a massive amount of communications between devices are required. Meanwhile, mm waves operating at high frequencies possess unique propagation behavior compared to typical RF (radio frequency) signals. Consequently, challenges arise for the architecture and packaging of telecommunication systems with a major focus on minimizing transmission loss. At such a short wavelength, the physical dimensions of electronic packages and interconnects become significant as they act as a transmission line, contributing to signal loss. For example, a bond pad becomes capacitive, a wire bond becomes inductive, and so on. Hence, reducing form factor is not only desirable for product miniaturization but is also beneficial to reduce the aforementioned signal losses. This gives rise to integrating devices directly on a substrate such as Antenna-in-Package (AiP) and integrated passive devices (IPDs) to fully benefit from the smaller form factor.

Flexible electronics have emerged as promising solutions for device miniaturization as they provide numerous advantages including higher circuit density, thinner profile, lighter weight, and shape conformance capability (foldable and bendable) as compared to their rigid counterpart of printed circuit board (PCB). In terms of processing, flexible electronics also offer competitive cost and efficiency due to their reel-to-reel manufacturing capability.

Base film substrate material plays a significant role in signal transmission characteristics. Low dielectric constant and loss tangent is desired to minimize insertion loss while low relative permittivity is required to decrease latency (signal delay). Owing to the sensitivity of mm wave performance with respect to material properties, the choice of dielectric material becomes more stringent.

With the increasing awareness of health more than ever before, wearable electronic devices for health care monitoring have also been growing rapidly. Wearable devices offer an attractive approach to medical diagnostics by providing remote health monitoring. It allows healthcare personnel to monitor physiological signs of patients in real time and to provide assessment of the health conditions remotely.

Among many health condition parameters, biopotentials such as electrocardiogram (ECG), electroencephalogram (EEG), electromyogram (EMG), electrooculogram (EOG), etc which measure the electrical output of human body activity from different body parts are excellent indicators of health condition. For example, an ECG signal indicates heart activity by measuring the electrical current induced by depolarization and repolarization that occur on a cardiac cycle (heartbeat) which is useful to detect various cardiovascular diseases (CVD). To detect this electrical current, sensing electrodes are required to be attached directly onto human skin at different locations. To enable non-invasive long term health monitoring, this biosensor has to be conformable with skin (biocompatible) and mechanically flexible.

Conventionally, a silver/silver chloride (Ag/AgCl) wet electrode with conductive gel has been used for biopotential sensors. Despite its excellent signal acquisition performance, a wet electrode suffers many drawbacks especially for wearable devices and long term monitoring. First, the application of wet electrodes require skin preparation which typically requires medical personnel. Second, the conductive gel dries out over time which degrades the signal quality and thus needs to be changed frequently which leads to the aforementioned problem. Finally, the conductive gel might cause irritation to skin, allergic reactions, inflammation, etc. Therefore, a dry electrode without the need of a conductive gel is a more suitable alternative for wearables and a long term monitoring system. Using a biocompatible flexible substrate and a noble metal as the contact electrode, a dry electrode that conforms to the skin can be used as a biopotential sensor. With direct contact between the skin and the noble metal, less signal noise resulting from skin motion artifacts can also be achieved.

U.S. Patent Applications 2016/0378071 (Rothkopf), 2018/0248245 (Okada), and 2020/0117068 (Yamazaki et al) include COP substrates. U.S. Patent Application 2016/0369812 (Narita et al) discloses a flexible substrate.

### SUMMARY

A principal object of the present disclosure is to provide a method of producing a flexible substrate for a semiconductor package having superior low loss characteristics.

Another object of the disclosure is to provide a method of producing a cyclo-olefin polymer flexible substrate for a semiconductor package having superior low loss characteristics.

A further object of the disclosure is to provide a method of producing a cyclo-olefin polymer flexible substrate for a semiconductor package having superior low loss characteristics and a method of directly metallizing the COP surface.

Yet another object is to provide a method of producing a cycl-olefin polymer flexible substrate for integrated circuit packaging of communication devices using direct metallization of the COP surface.

A still further object is to provide a method of producing a cycl-olefin polymer flexible substrate for use in biocompatible sensor devices.

According to the objects of the disclosure, a method to produce a flexible substrate is achieved. A base film material of cyclo-olefin polymer (COP) is provided. A surface of the COP base film is irradiated with UV light to form a functional group on the COP surface. Thereafter, the surface is treated with an alkaline degreaser. Thereafter, a Ni—P seed layer is electrolessly plated on the surface. A photoresist pattern is formed on the Ni—P seed layer. Copper traces are plated within the photoresist pattern. The photoresist pattern is removed and the Ni—P seed layer not covered by the copper traces is etched away to complete the flexible substrate.

Also according to the objects of the disclosure, another method of manufacturing a flexible substrateis achieved. .A base film material of cyclo-olefin polymer (COP) is provided. A surface of the COP base film is selectively irradiated with UV light to form a functional group in a pattern on the COP surface. Thereafter, the surface is treated with an alkaline degreaser. Thereafter, a catalyst is deposited on the irradiated pattern on the surface. Thereafter, copper traces are plated on the catalyst to complete the flexible substrate.

Also according to the objects of the disclosure, a method of manufacturing a semiconductor package for a millimeter scale wavelength communication module is achieved. A flexible substrate with an embedded antenna is provided as follows. A base film material of cyclo-olefin polymer (COP) is provided. A surface of the COP base film is irradiated with UV light to form a functional group on the COP surface. Thereafter, the surface is treated with an alkaline degreaser. Thereafter, a catalyst is deposited on the surface and, thereafter, copper traces and an embedded antenna are plated on the catalyst to complete the flexible substrate. A surface finishing layer is plated on the copper traces but not on the embedded antenna and at least one electronic component is mounted on the flexible substrate.

Also according to the objects of the disclosure, a method of manufacturing a semiconductor package is achieved. A base film material of cyclo-olefin polymer (COP) is provided. A surface of the COP base film is irradiated with UV light to form a functional group on the COP surface. Thereafter, the surface is treated with an alkaline degreaser. Thereafter, a catalyst is deposited on the surface. Thereafter, copper traces are plated on the catalyst to complete the flexible substrate. A surface finishing layer is plated on the copper traces and at least one electronic component is mounted on the flexible substrate.

Also according to the objects of the disclosure, a method of manufacturing a biocompatible flexible substrate is achieved. A base film material of cyclo-olefin polymer (COP) is provided. A surface of the COP base film is irradiated with UV light to form a functional group on the COP surface. Thereafter, the surface is treated with an alkaline degreaser. Thereafter, a Ni—P seed layer is electrolessly plated on the surface. A photoresist pattern is formed on the Ni—P seed layer. Biocompatible surface finishing is plated within the photoresist pattern. The photoresist pattern is removed and the Ni—P seed layer not covered by the biocompatible surface finishing is etched away to complete the biocompatible flexible substrate.

Also according to the objects of the disclosure, another method of manufacturing a biocompatible flexible substrate is achieved. A base film material of cyclo-olefin polymer (COP) is provided. A surface of the COP base film is selectively irradiated with UV light to form a functional group in a pattern on the COP surface. Thereafter the surface is treated with an alkaline degreaser. Thereafter a catalyst is deposited on the irradiated pattern on the surface. Thereafter a Ni—P seed layer is electrolessly plated on the surface. Thereafter biocompatible surface finishing is plated on the Ni—P seed layer to complete the biocompatible flexible substrate.

### BRIEF DESCRIPTION OF THE DRAWINGS

In the accompanying drawings forming a material part of this description, there is shown:

FIGS. 1A-1J schematically illustrate in oblique representation steps in a first preferred embodiment of the present disclosure.

FIGS. 2A-2E schematically illustrate in oblique representation steps in a second preferred embodiment of the present disclosure.

FIG. 3 is a cross-sectional representation of a completed communication module using the COP flexible substrate of the present disclosure.

FIG. 4 is a cross-sectional representation of a completed semiconductor package using the COP flexible substrate of the present disclosure.

FIG. 5A-5C illustrate steps in a third embodiment of the present disclosure.

FIGS. 6A-6B illustrate steps in a fourth embodiment of the present disclosure.

### DESCRIPTION OF THE PREFERRED EMBODIMENTS

Cyclo-Olefin Polymer (COP) emerges as a promising material to fulfill future device requirements with superior low loss characteristics compared to high performance materials such as liquid crystal polymer (LCP), modified polyimide (MPI), polyimide (PI), and polyethylene terephthalate (PET). In addition, COP also offers excellent properties in terms of chemical resistance, water adsorption, gas permeability, and light transmission. On the other hand, conductor roughness is also critical to minimize the signal loss as skin effect (tendency of current to be distributed near the conductor surface) becomes more significant as signal frequency increases. Therefore, forming a smooth conductor surface on top of the COP material as a circuitry pattern is an attractive electronic packaging solution to minimize both dielectric and conductor losses which are essential for 5G devices. Directly metallizing the COP surface also opens up fabrication of integrated devices such as Antenna-in-Package (AiP). Furthermore, due to its unique optical properties, COP can also be integrated with optical interconnect for applications involving high volume data transmission.

COP suffers from a low melting temperature that limits the processing capability and subsequently its potential to be used in electronic packaging as the assembly process of electronic components typically requires a high temperature that degrades the COP. Overcoming these challenges will enable COP to be used as a superior packaging substrate for future communication devices.

The present disclosure describes the construction and fabrication method using cyclo-olefin polymer (COP) base film material that is flexible and possesses low dielectric constant/loss tangent and excellent biocompatibility, thus is suitable for both IC Packaging of Communication Devices (mmWave) and Biocompatible Sensors Devices.

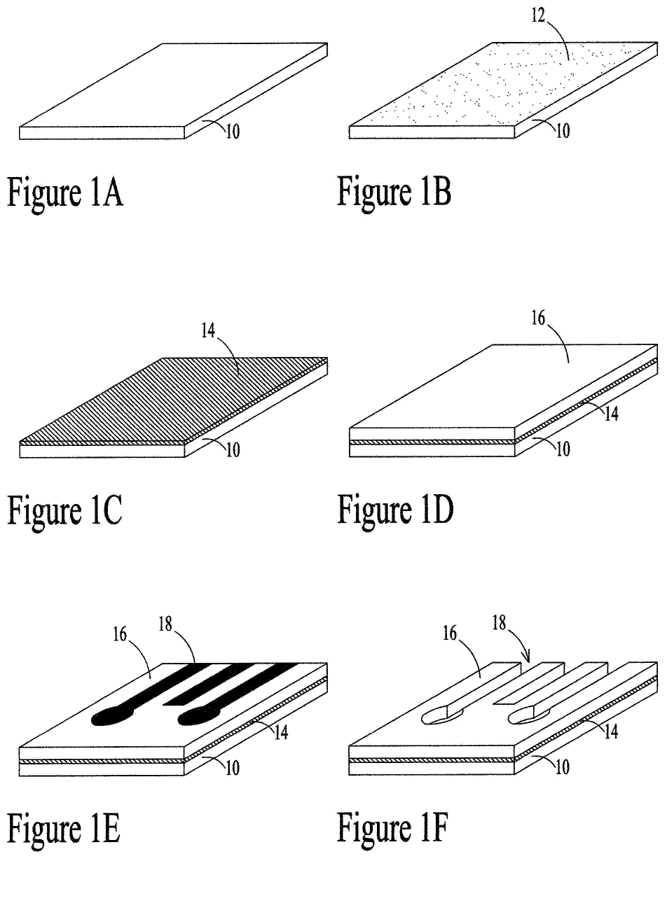

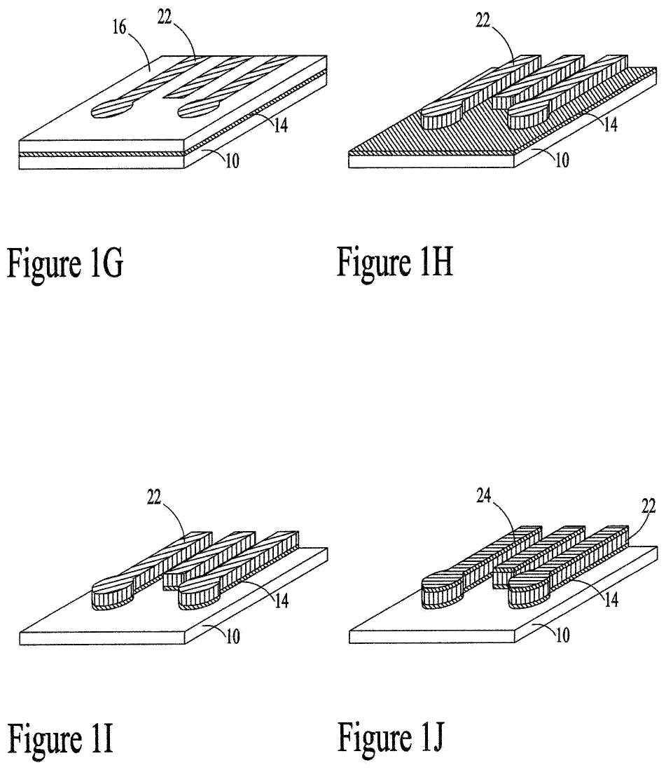

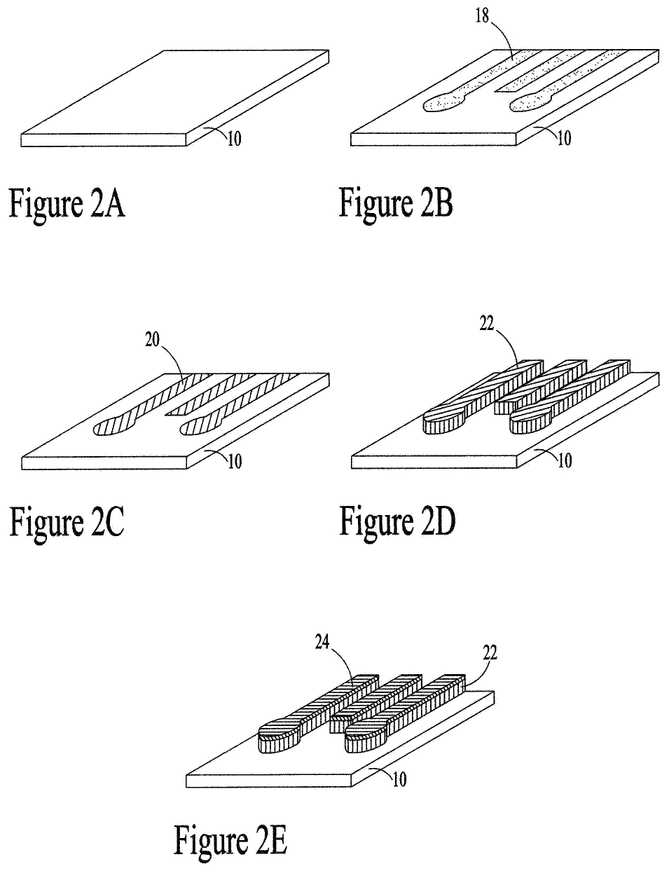

Referring now to FIGS. 1A-1J, a first preferred embodiment in the process of the present disclosure will be described in detail. The process uses low temperature assembly techniques to enable the use of COP as a reliable packaging substrate. The process begins with a flexible base dielectric material substrate 10 of cyclo-olefin polymer (COP), shown in FIG. 1A. COP 10 has a preferred thickness of between about 12.5 and 100 μm, as shown in FIG. 2A. The COP material layer has a dielectric constant <3 and a dielectric tangent loss <0.001 at 1 GHz. The COP also has a refractive index lower than the refractive index of commonly used waveguide materials such as silicon, silicon dioxide, gallium arsenide, gallium phosphide, and the like, as required to form optical interconnects for some applications.

Now, as shown in FIG. 1B, the surface of the COP 10 is modified by irradiating the COP surface using ultra-violet (UV) light to alter the resin surface and create a functional group 12. A wavelength of between about 184.9 nm and 253.7 nm is applied for 5 to 20 minutes with an irradiation intensity of between about 5 to 50 mW/cm², forming a carbonyl and hydroxyl group 12 with thickness of 2 to 20 nm. The functional group 12 creates a bond between the COP film 10 and metal to be deposited on top of it.

Next, the surface is treated with an alkaline degreaser in a typical cleaning process. Now, a catalyst layer, not shown, is deposited onto the irradiated surface 12 of the COP base 10 by immersion into an ionic metal solution. Typically, Palladium (Pd) or Nickel (Ni) is deposited to activate the surface for subsequent electroless Ni—P plating. As shown in FIG. 2C, an autocatalytic nickel-phosphorus (Ni—P) seed layer 14 is applied over the catalyst on the UV irradiated COP film using an electroless plating process. The composition of Ni—P in the seed layer is Ni: 96.5˜97.5 wt %, P: 2.5˜3.5 wt %. The thickness of the Ni—P layer is ideally 0.1 μm+/−10%. In some applications, the Ni—P can be in a different ratio and the thickness can be in the range of 0.1-1.0 μm.

As shown in FIG. 1D, a layer of photoresist 16, preferably a positive-acting photoresist, is applied to the seed layer surface of the substrate. The photoresist may be a dry film or a liquid photoresist. In the photolithography process, the photoresist is exposed (FIG. 1E) and developed (FIG. 1F) to form a fine pitch trace pattern 18 for circuitization.

In FIG. 1G a layer of conductive metal 22 is plated up to the desired thickness using electrolytic copper plating. The plating is employed only on the areas of the spacing which are not covered by the photoresist. In some applications, the plating is controlled to be at an aspect ratio of close to 1. The ratio of the top to bottom widths of the traces using this method can be close to 1. The copper is a fine-grained deposit with highly ductile properties. The thickness of copper is about 8 μm. In some applications, the thickness of electrolytic copper can be in a range of 2-35 μm. The elongation strength of the copper deposit is over 15% with a tensile strength of between 290-340 N/mm². The hardness of electrolytic copper is 100 in vicker hardness with a purity of more than 99.9%. The copper is directly built up on electroless N-Pi which is an innately a smooth surface, resulting in an extremely smooth copper surface.

The photoresist layer 16 is stripped, as shown FIG. 1H, followed by etching away the Ni—P seed layer 14 not covered by the copper traces using a hydrogen peroxide acidic base solution that is strictly controlled to etch the Ni—P seed layer in a unidirectional manner with no or minimal etch on the copper trace to maintain the copper trace aspect ratio of close to 1, as shown in FIG. 1I.

A protective layer of surface finishing is preferably plated on top of the copper circuitry. For example, FIG. 1J illustrates surface finishing layer 24 on copper traces 22. The surface finishing layer 24 may be electrolytic Ni/Au, electroless Nickel/Immersion gold (ENIG), Electroless Ni/autocatalytic Au (EPAG), Electroless Nickel/Electroless Palladium/Immersion Gold (ENEPIG), Immersion Au/Electroless Pd/Immersion Au (IGEPIG), Immersion Sn, Electrolytic Palladium, or electrolytic Titanium. A Ni-free surface finish is preferable to support the high frequency signal transmission.

This completes formation of the traces on the flexible substrate. The manufacturing method described results in an extremely smooth surface with RA <25 nm without compromising trace adhesion. This smooth surface is able to minimize the conductor loss during signal transmission. Trace adhesion strength and bend durability is similar to, if not better than, that of a substrate fabricated by a conventional subtractive process using a sputtering type base film material.

The second preferred embodiment of the present disclosure is described with reference to FIGS. 2A-2H. The process begins with a flexible dielectric base material of cyclo-olefin polymer (COP) 10. Dielectric 10 has a preferred thickness of between about 12.5 and 100 μm, as shown in FIG. 2A. As in the first preferred embodiment, the COP material layer has a dielectric constant <3 and a dielectric tangent loss <0.001 at 1 GHz. The COP also has a refractive index lower than the refractive index of commonly used waveguide materials such as silicon, silicon dioxide, gallium arsenide, gallium phosphide, and the like, as required to form optical interconnects for some applications.

Now, the COP surface is selectively irradiated by means of a photo mask/direct imaging technique using UV light to alter the resin surface and create a functional group as shown by 18 in FIG. 2B. A wavelength of between about 184.9 nm and 253.7 nm is applied for 5 to 20 μminutes with an irradiation intensity of between about 5 to 50 mW/cm², forming a carbonyl and hydroxyl group 18 with thickness of 2 to 20 nm where the COP surface is not covered by the photo mask. The photo mask is removed and the surface is treated with an alkaline degreaser in a typical cleaning process.

Next, a catalyst is deposited by immersion into an ionic metal solution. Typically Palladium(Pd) or Nickel (Ni) is deposited to activate the surface for subsequent electroless plating. The catalyst 20 deposits only on the irradiated pattern 18, as shown in FIG. 2C.

As shown in FIG. 2D, a layer of conductive metal 22 is plated up to the desired thickness using electrolytic copper plating. The plating only occurs on the areas that have had the catalyst deposited thereon. In some applications, the plating is controlled to be at an aspect ratio of close to 1. The ratio of the top to bottom widths of the traces using this method can be close to 1. The copper is a fine-grained deposit with highly ductile properties. The thickness of copper is about 4 μm. In some applications, the thickness of electrolytic copper can be in a range of 1-10 μm. The elongation strength of the copper deposit is over 15% with a tensile strength of between 200-550 N/mm². The elimination of the electroless Ni—P layer, which possesses ferromagnetic properties, helps to further minimize signal loss.

In some applications, autocatalytic nickel-phosphorus (Ni—P) as a seed layer can be applied over the UV irradiated COP film using an electroless plating process prior to the electroless copper plating. In this case, the Ni—P thickness is ideally 0.1 μm+/−10%. The composition of Ni—P in the seed layer is Ni: 96.5˜97.5 wt %, P: 2.5˜3.5 wt %. In some applications, the Ni—P can be in a different ratio and the thickness can be in the range of 0.1-1.0 μm.

This completes formation of the traces 22 on the flexible substrate. As in the first embodiment, the manufacturing method of the second embodiment results in an extremely smooth surface with RA <25 nm without compromising trace adhesion, This smooth surface is able to minimize the conductor loss during signal transmission. Trace adhesion strength and bend durability is similar to, if not better than, that of a substrate fabricated by a conventional subtractive process using a sputtering type base film material.

A protective layer of surface finishing is preferably plated on top of the copper circuitry. For example, FIG. 2E illustrates surface finishing layer 24 on copper traces 22. The surface finishing layer 24 may be electrolytic Ni/Au, electroless Nickel/Immersion gold (ENIG), Electroless Ni/autocatalytic Au (EPAG), Electroless Nickel/Electroless Palladium/Immersion Gold (ENEPIG), Immersion Au/Electroless Pd/Immersion Au (IGEPIG), Immersion Sn, Electrolytic Palladium, electrolytic Platinum, electrolytic Silver, electrolytic Tantalum, or electrolytic Titanium. A Ni-free surface finish is preferable to support the high frequency signal transmission.

After completing the formation of traces on the flexible substrate according to either the first or the second preferred embodiment, a semiconductor package for a mmwave communication module may be manufactured. The traces may form an embedded antenna design. The surface finishing layer 24 should not be formed on the embedded antenna.

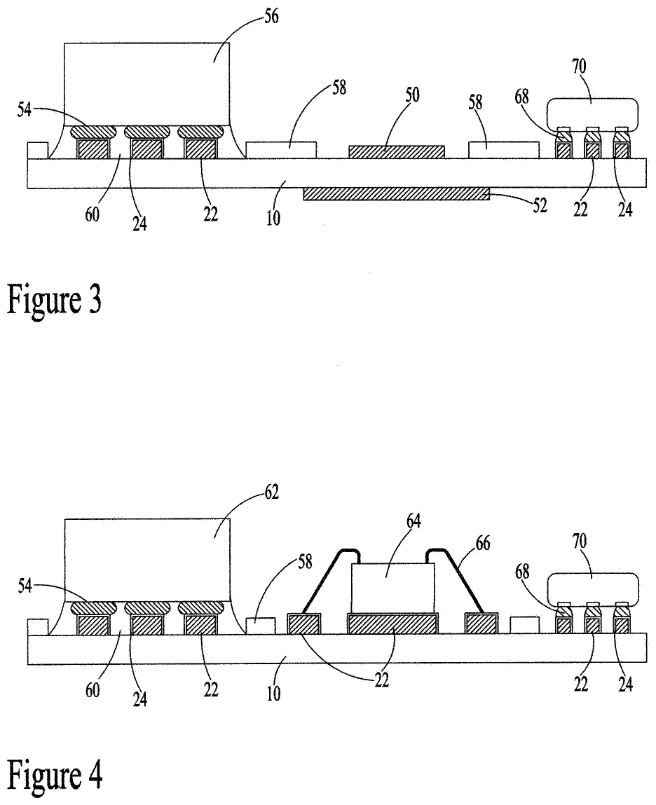

Electronic components are assembled onto the flexible substrate. FIG. 3 illustrates a exemplary communication module for 5G applications using the COP base film substrate 10 of the present disclosure. An antenna patch 50 is illustrated on one surface of the COP flexible substrate 10 while an antenna ground 52 is shown on the opposite surface of the substrate. Copper traces 22 with surface finishing 24 are illustrated on the left and right sides of the figure. Components such as the radio frequency integrated circuit chip (RFIC) 56 are mounted onto copper traces 22 using, for example, gold bumps 54. Solder mask 58 and underfill 60 are also illustrated. The RFIC 56 can act as a transmitter or as a receiver. Component 70 is mounted onto copper traces 22 using solder bumps 68, for example.

The assembly method for both the first level of device to package and the second level of interconnect of the package to the main board can be using low temperature interconnect materials to prevent degradation on the COP material. These materials can include low melting temperature solder metallurgy, conductive adhesive film (such as anisotropic conductive film, isotropic conductive film, or non-conductive film), or curable printed conductive ink.

After completing the formation of traces on the flexible substrate according to either the first or the second preferred embodiment, a semiconductor package may be manufactured. Electronic components are then assembled onto the flexible substrate. FIG. 4 illustrates a exemplary semiconductor package using the COP base film substrate of the present disclosure. Copper traces 22 with surface finishing 24 are illustrated on the COP substrate 10. Components 62, 64, and 70 are mounted onto copper traces 22 using, for example, gold bumps 54, surface mount technology, and solder bumps 68, respectively. Solder mask 58, underfill 60, and wire bonds, 66, for example, are also illustrated. The electronic components can be active devices with different functionalities such as RF (Radio Frequency) IC, memory chips, logic IC, converter IC, power management IC, application specific IC (ASIC), microcontroller unit (MCU), display driver IC, touch driver IC, touch and display drive integration (TDDI) IC, biometrics sensor and controller IC, and so on, as well as passive devices such as capacitors and inductors.

The assembly method can be using low temperature interconnect materials to prevent degradation on the COP material. These materials can include low melting temperature solder metallurgy, conductive adhesive film (such as anisotropic conductive film, isotropic conductive film, or non-conductive film), or curable printed conductive ink.

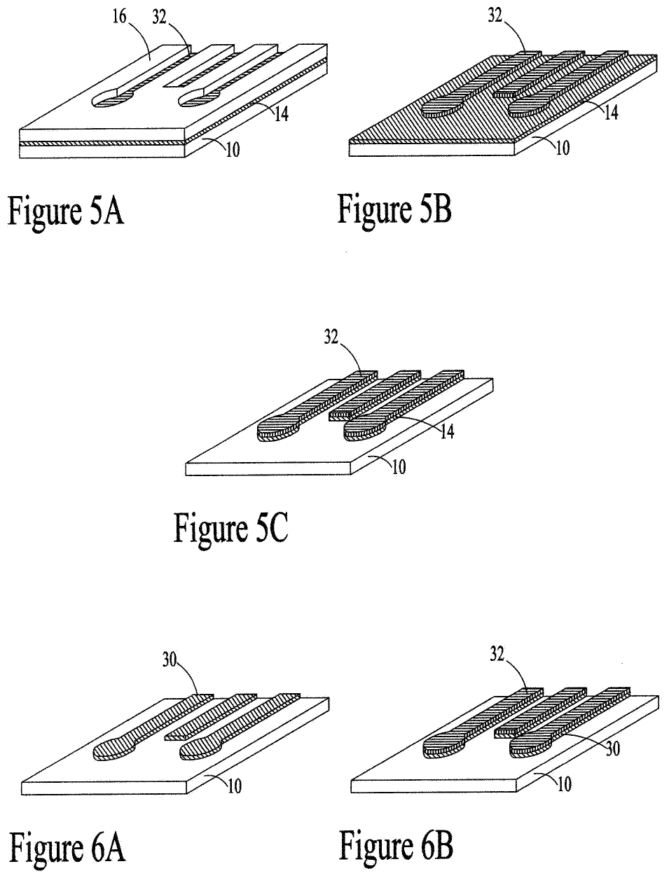

Furthermore, a biocompatible flexible substrate can be provided according to the present disclosure. A third preferred embodiment of the present disclosure will be described with reference to FIGS. 1A-1F and 5A-5C. As described above for the first preferred embodiment, the process begins with a flexible base dielectric material substrate 10 of cyclo-olefin polymer (COP), shown in FIG. 1A. COP 10 has a preferred thickness of between about 12.5 and 100 μm. The COP material layer has a dielectric constant <3 and a dielectric tangent loss <0.001 at 1 GHz. The COP also has a refractive index lower than the refractive index of commonly used waveguide materials such as silicon, silicon dioxide, gallium arsenide, gallium phosphide, and the like, as required to form optical interconnects for some applications.

Fabrication continues as described for the first embodiment with irradiating the COP surface using ultra-violet (UV) light to alter the resin surface and create a functional group 12, as shown in FIG. 1B, treating with an alkaline degreaser, then depositing a Palladium (Pd) or Nickel (Ni) catalyst layer, followed by an autocatalytic nickel-phosphorus (Ni—P) seed layer 14 applied over the catalyst on the UV irradiated COP film using an electroless plating process, as shown in FIG. 1C. The Ni—P thickness is ideally 0.1 μm+/−10%. The composition of Ni—P in the seed layer is Ni 96.5˜97.5 wt %, P: 2.5˜3.5 wt %.

As shown in FIG. 1D, a layer of photoresist 16, preferably a positive-acting photoresist, is applied to the Ni—P seed layer surface of the substrate. The photoresist may be a dry film or a liquid photoresist. In the photolithography process, the photoresist is exposed (FIG. 1E) and developed (FIG. 1F) to form a fine pitch trace pattern 18.

Now, referring to FIG. 5A, biocompatible surface finishing 32 is plated on the Ni—P seed layer exposed within the photoresist pattern. Plating surface finishing 32 comprises electrolytic Palladium, electrolytic Platinum, electrolytic Silver, electrolytic Titanium, electrolytic Tantalum, electrolytic Tungsten, immersion Tin, Electroless Palladium/Autocatalytic Gold (EPAG), or Immersion Gold/Electroless Palladium/Immersion Gold (IGEPIG).

Next, as illustrated in FIG. 5B, the photoresist pattern 16 is stripped and then the Ni—P seed layer 14 not covered by the biocompatible surface finishing 30 is etched away, as shown in FIG. 5C, to complete the biocompatible flexible substrate.

In a fourth preferred embodiment of the present disclosure, an alternative method of fabricating a biocompatible flexible substrate is described with reference to FIGS. 2A-2C and FIGS. 6A-6B. As described in the process of the second embodiment, the process begins with a flexible dielectric base material of cyclo-olefin polymer (COP) 10 as shown in FIG. 2A.

Now, the COP surface is selectively irradiated by means of a photo mask/direct imaging technique using UV light to alter the resin surface and create a functional group as shown by 18 in FIG. 2B. A wavelength of between about 184.9 nm and 253.7 nm is applied for 5 to 20 μminutes with an irradiation intensity of between about 5 to 50 mW/cm², forming a carbonyl and hydroxyl group 18 with thickness of 2 to 20 nm where the COP surface is not covered by the photo mask. The photo mask is removed and the surface is treated with an alkaline degreaser in a typical cleaning process.

Next, a catalyst is deposited by immersion into an ionic metal solution. Typically Palladium(Pd) or Nickel (Ni) is deposited to activate the surface for subsequent electroless plating. The catalyst 20 deposits only on the irradiated pattern 18, as shown in FIG. 2C.

Now, referring to FIG. 6A, for a biocompatible flexible substrate, a Ni—P seed layer 30 is plated on the COP substrate in an autocatalytic process. The plating only occurs on the areas that have had the catalyst deposited thereon. The Ni—P layer has a preferred thickness of 0.1 μm+/−10% and a composition of Ni: 96.5˜97.5 wt % and P: 2.5˜3.5 wt %.

Finally, as shown in FIG. 6B, a biocompatible surface finishing 32 is plated on the Ni—P seed layer 30 to complete the biocompatible flexible substrate. The surface finishing process comprises electrolytic Palladium, electrolytic Platinum, electrolytic Silver, electrolytic Titanium, electrolytic Tantalum, electrolytic Tungsten, immersion Tin, Electroless Palladium/Autocatalytic Gold (EPAG), or Immersion Gold/Electroless Palladium/Immersion Gold (IGEPIG).

The biocompatible flexible substrates of the third and fourth embodiments can be used in medical devices, medical patches, medical imaging/diagnosis devices, implantable biomedical devices, or lab-on-flex.

The present disclosure has described a method of manufacturing a flexible substrate for a semiconductor package with superior signal transmission performance or a biocompatible flexible substrate especially useful for high frequency for Internet of Things (IoTs), sensors (smart home, smart packaging, autonomous driving), smart wearables (virtual reality/augmented reality (VR/AR), electronic skin, wearable patch), optoelectronics (data storage, data transmission, communication modules), medical devices (medical patch, medical imaging/diagnosis devices, implantable biomedical devices, lab-on-flex), and industrials (building & machinery monitoring/automation).

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A method of manufacturing a flexible substrate comprising:
providing a base film material of cyclo-olefin polymer;
irradiating a surface of said cyclo-olefin polymer base film with UV light to form a functional group on said cyclo-olefin polymer surface;
thereafter electrolessly plating a Ni—P seed layer on said surface;
forming a photoresist pattern on said Ni—P seed layer;
plating copper traces within said photoresist pattern; and
removing said photoresist pattern and etching away said Ni—P seed layer not covered by said copper traces to complete said flexible substrate.

2. The method according to claim 1 wherein said cyclo-olefin polymer base material has a thickness of 12.5 to 100 μm, a dielectric constant of <3, and a dielectric tangent loss of <0.001 at 1 GHz.

3. The method according to claim 1 wherein said irradiating said cyclo-olefin polymer surface forms said functional group comprising a carbonyl and hydroxyl group layer having a thickness of 2 to 20 nm.

4. The method according to claim 1 further comprising depositing a catalyst layer comprising Palladium (Pd) or Nickel (Ni) on said cyclo-olefin polymer surface by immersion into an ionic metal solution to activate said surface for subsequent electroless Ni—P seed layer plating.

5. The method according to claim 4 further comprising treating said surface with an alkaline degreaser prior to said depositing said catalyst layer.

6. The method according to claim 1 wherein said electrolessly plating said Ni—P seed layer is an autocatalytic process and wherein said Ni—P seed layer has a thickness of 0.1 μm+/−10% and a composition of Ni: 96.5˜97.5 wt % and P: 2.5˜3.5 wt %.

7. The method according to claim 1 wherein said forming said photoresist pattern comprises:
applying a photoresist on said Ni—P seed layer; and
exposing and developing said photoresist to form a pattern for fine pitch traces for circuitization.

8. The method according to claim 1 wherein said plating said copper traces comprises electrolytically plating copper to a thickness of between about 2 to 35 μm wherein a ratio of the top to bottom widths of said copper traces is close to 1, wherein an elongation strength of said copper traces is over 15%, wherein a tensile strength of said copper traces is between about 290 and 340 N/mm², and wherein a hardness of said copper traces is 100 in vicker hardness with a purity of more than 99.9%.

9. A method of manufacturing a flexible substrate comprising:
providing a base film material of cyclo-olefin polymer;
selectively irradiating a surface of said cyclo-olefin polymer base film with UV light to form a functional group in a pattern on said cyclo-olefin polymer surface;
thereafter depositing a catalyst on irradiated said pattern on said surface; and
thereafter plating copper traces on said catalyst to complete said flexible substrate.

10. The method according to claim 9 wherein said cyclo-olefin polymer base material has a thickness of 12.5 to 100 μm, a dielectric constant of <3, and a dielectric tangent loss of <0.001 at 1 GHz.

11. The method according to claim 9 wherein said selectively irradiating said cyclo-olefin polymer surface forms said functional group comprising a carbonyl and hydroxyl group layer having a thickness of 2 to 20 nm in said pattern defined by a photo mask.

12. The method according to claim 9 further comprising treating said surface with an alkaline degreaser prior to depositing said catalyst.

13. The method according to claim 9 wherein said depositing a catalyst layer comprises depositing Palladium (Pd) or Nickel (Ni) on said cyclo-olefin polymer surface by immersion into an ionic metal solution to activate said surface for subsequent electroless plating.

14. The method according to claim 9 further comprising electrolessly plating a Ni—P seed layer on said catalyst in an autocatalytic process, wherein said Ni—P seed layer has a thickness of 0.1 μm+/−10% and a composition of Ni: 96.5˜97.5 wt % and P: 2.5˜3.5 wt %.

15. The method according to claim 9 wherein said plating said copper traces comprises electrolytically plating copper to a thickness of between about 2 to 35 μm wherein a ratio of the top to bottom widths of said copper traces is close to 1, wherein an elongation strength of said copper traces is over 15%, wherein a tensile strength of said copper traces is between about 200 and 550 N/mm², and wherein a hardness of said copper traces is 100 in vicker hardness with a purity of more than 99.9%.

16. A method of manufacturing a semiconductor package for a millimeter scale wavelength communication module comprising:
providing a flexible substrate with an embedded antenna comprising:
providing a base film material of cyclo-olefin polymer;
irradiating a surface of said cyclo-olefin polymer base film with UV light to form a functional group on said cyclo-olefin polymer surface;
thereafter depositing a catalyst on said surface; and
thereafter plating copper traces and an embedded antenna on said catalyst to complete said flexible substrate;
plating a surface finishing layer on said copper traces but not on said embedded antenna; and
mounting at least one electronic component on said flexible substrate.

17. The method according to claim 16 wherein said cyclo-olefin polymer base material has a thickness of 12.5 to 100 μm, a dielectric constant of <3, and a dielectric tangent loss of <0.001 at 1 GHz.

18. The method according to claim 16 wherein said irradiating said cyclo-olefin polymer surface forms said functional group comprising a carbonyl and hydroxyl group layer on said cyclo-olefin polymer surface.

19. The method according to claim 16 wherein said irradiating said cyclo-olefin polymer surface comprises:
forming a photo mask pattern on said cyclo-olefin polymer surface; and
irradiating said cyclo-olefin polymer surface in said photo mask pattern to form said functional group comprising a carbonyl and hydroxyl group layer on said pattern on said cyclo-olefin polymer surface.

20. The method according to claim 16 wherein said depositing a catalyst comprises depositing Palladium (Pd) or Nickel (Ni) on irradiated said cyclo-olefin polymer surface by immersion into an ionic metal solution to activate said surface for subsequent electroless plating.

21. The method according to claim 16 further comprising treating said surface with an alkaline degreaser prior to said depositing said catalyst.

22. The method according to claim 16 further comprising electrolessly plating a Ni—P seed layer on said catalyst in an autocatalytic process, wherein said Ni—P seed layer has a thickness of 0.1 μm+/−10% and a composition of Ni: 96.5˜97.5 wt % and P: 2.5˜3.5 wt %.

23. The method according to claim 16 wherein said plating said copper traces comprises electrolytically plating copper to a thickness of between about 2 to 35 μm wherein a ratio of the top to bottom widths of said copper traces is close to 1, wherein an elongation strength of said copper traces is over 15%, wherein a tensile strength of said copper traces is between about 200 and 550 N/mm², and wherein a hardness of said copper traces is 100 in vicker hardness with a purity of more than 99.9%.

24. The method according to claim 16 wherein said surface finishing layer comprises electrolytic Ni/Au, electroless Nickel/Immersion gold (ENIG), Electroless Nickel/Electroless Palladium/Immersion Gold (ENEPIG), electrolytic Palladium, electrolytic Platinum, electrolytic Silver, electrolytic Tantalum, electrolytic Titanium, electrolytic Tin, electrolytic Rhodium, Electroless Palladium/Autocatalytic Gold (EPAG), or Immersion Gold/Electroless Palladium/Immersion Gold (IGEPIG).

25. The method according to claim 16 wherein at least one said electronic component is a radio frequency integrated circuit acting as a transmitter or a receiver.

26. The method according to claim 16 wherein said mounting uses low temperature interconnect materials including low melting temperature solder metallurgy, conductive adhesive film, anisotropic conductive film, isotropic conductive film, non-conductive film, or curable printed conductive ink.

27. The method according to claim 16 wherein said semiconductor package is used in one of the group containing: Internet of Things, smart home sensors, smart packaging sensors, autonomous driving sensors, smart wearables, virtual reality/augmented reality, electronic skin, wearable patches, data storage optoelectronics, data transmission optoelectronics, optoelectronics communication modules, medical devices, medical patches, medical imaging/diagnosis devices, implantable biomedical devices, lab-on-flex, and building and machinery monitoring/automation devices.

28. A method of manufacturing a semiconductor package comprising:
providing a flexible substrate comprising:
providing a base film material of cyclo-olefin polymer;
irradiating a surface of said cyclo-olefin polymer base film with UV light to form a functional group on said cyclo-olefin polymer surface;
thereafter depositing a catalyst on said surface; and
thereafter plating copper traces on said catalyst to complete said flexible substrate;
plating a surface finishing layer on said copper traces; and
mounting at least one electronic component on said flexible substrate.

29. The method according to claim 28 wherein said cyclo-olefin polymer base material has a thickness of 12.5 to 100 μm, a dielectric constant of <3, and a dielectric tangent loss of <0.001 at 1 GHz.

30. The method according to claim 28 wherein said irradiating said cyclo-olefin polymer surface forms said functional group comprising a carbonyl and hydroxyl group layer on said cyclo-olefin polymer surface.

31. The method according to claim 28 wherein said irradiating said cyclo-olefin polymer surface comprises
forming a photo mask pattern on said cyclo-olefin polymer surface; and irradiating said cyclo-olefin polymer surface in said photo mask pattern to form said functional group comprising a carbonyl and hydroxyl group layer on said pattern on said cyclo-olefin polymer surface.

32. The method according to claim 28 wherein said depositing a catalyst comprises depositing Palladium (Pd) or Nickel (Ni) on irradiated said cyclo-olefin polymer surface by immersion into an ionic metal solution to activate said surface for subsequent electroless plating.

33. The method according to claim 28 further comprising treating said surface with an alkaline degreaser prior to said depositing said catalyst.

34. The method according to claim 28 further comprising electrolessly plating a Ni—P seed layer on said catalyst in an autocatalytic process, wherein said Ni—P seed layer has a thickness of 0.1 μm+/−10% and a composition of Ni: 96.5˜97.5 wt % and P: 2.5˜3.5 wt %.

35. The method according to claim 28 wherein said plating said copper traces comprises electrolytically plating copper to a thickness of between about 2 to 35 μm wherein a ratio of the top to bottom widths of said copper traces is close to 1, wherein an elongation strength of said copper traces is over 15%, wherein a tensile strength of said copper traces is between about 200 and 550 N/mm², and wherein a hardness of said copper traces is 100 in vicker hardness with a purity of more than 99.9%.

36. The method according to claim 28 wherein said surface finishing layer comprises electrolytic Ni/Au, electroless Nickel/Immersion gold (ENIG), Electroless Nickel/Electroless Palladium/Immersion Gold (ENEPIG), electrolytic Palladium, electrolytic Platinum, electrolytic Silver, electrolytic Tantalum, electrolytic Titanium, electrolytic Tin, electrolytic Rhodium, Electroless Palladium/Autocatalytic Gold (EPAG), or Immersion Gold/Electroless Palladium/Immersion Gold (IGEPIG).

37. The method according to claim 28 wherein at least one said electronic component is chosen from the group containing: radio frequency integrated circuit memory chips, logic IC, converter IC, power management IC, application specific IC (ASIC), microcontroller unit (MCU), display driver IC, touch driver IC, touch and display drive integration (TDDI) IC, biometrics sensor and controller IC, passive devices, capacitors, and inductors.

38. The method according to claim 28 wherein said mounting uses low temperature interconnect materials including low melting temperature solder metallurgy, conductive adhesive film, anisotropic conductive film, isotropic conductive film, non-conductive film, or curable printed conductive ink.

39. The method according to claim 28 wherein said semiconductor package is used in one of the group containing: Internet of Things, smart home sensors, smart packaging sensors, autonomous driving sensors, smart wearables, virtual reality/augmented reality, electronic skin, wearable patches, data storage optoelectronics, data transmission optoelectronics, optoelectronics communication modules, medical devices, medical patches, medical imaging/diagnosis devices, implantable biomedical devices, lab-on-flex, and building and machinery monitoring/automation devices.

40. A method of manufacturing a biocompatible flexible substrate comprising:
providing a base film material of cyclo-olefin polymer (COP);
irradiating a surface of said COP base film with UV light to form a functional group on said COP surface;
thereafter treating said surface with an alkaline degreaser;
thereafter electrolessly plating a Ni—P seed layer on said surface;
forming a photoresist pattern on said Ni—P seed layer;
plating biocompatible surface finishing within said photoresist pattern; and
removing said photoresist pattern and etching away said Ni—P seed layer not covered by said biocompatible surface finishing to complete said flexible substrate.

41. The method according to claim 40 wherein said COP base material has a thickness of 12.5 to 100 μm, a dielectric constant of <3, and a dielectric tangent loss of <0.001 at 1 GHz.

42. The method according to claim 40 wherein said irradiating said COP surface comprises altering the COP surface to form carbonyl and hydroxyl group layer with thickness of 2 to 20 nm.

43. The method according to claim 40 further comprising depositing a catalyst layer comprising Palladium (Pd) or Nickel (Ni) on said COP surface by immersion into an ionic metal solution to activate said surface for subsequent electroless Ni—P seed layer plating.

44. The method according to claim 43 wherein said treating said surface with an alkaline degreaser comprises cleaning the surface from any contaminants prior to said depositing said catalyst layer

45. The method according to claim 40 wherein said electrolessly plating said Ni—P seed layer is an autocatalytic process and wherein said Ni—P seed layer has a thickness of 0.1 μm+/−10% and a composition of Ni: 96.5˜97.5 wt % and P: 2.5˜3.5 wt %.

46. The method according to claim 40 wherein said forming said photoresist pattern comprises:
applying a photoresist on said Ni—P seed layer; and
exposing and developing said photoresist to form a pattern for fine pitch traces.

47. The method according to claim 40 wherein said plating said surface finishing comprises electrolytic Palladium, electrolytic Platinum, electrolytic Silver, electrolytic Titanium, electrolytic Tantalum, electrolytic Tungsten, immersion Tin, Electroless Palladium/Autocatalytic Gold (EPAG), or Immersion Gold/Electroless Palladium/Immersion Gold (IGEPIG).

48. The method according to claim 40 wherein said biocompatible flexible substrate is used in one of the group containing: medical devices, medical patches, medical imaging/diagnosis devices, implantable biomedical devices, and lab-on-flex.

49. A method of manufacturing a biocompatible flexible substrate comprising:
providing a base film material of cyclo-olefin polymer (COP);
selectively irradiating a surface of said COP base film with UV light to form a functional group in a pattern on said COP surface;
thereafter treating said surface with an alkaline degreaser;
thereafter depositing a catalyst on said irradiated pattern on said surface;
thereafter electrolessly plating a Ni—P seed layer on said surface; and
thereafter plating biocompatible surface finishing to complete said flexible substrate.

50. The method according to claim 49 wherein said COP base material has a thickness of 12.5 to 100 μm, a dielectric constant of <3, and a dielectric tangent loss of <0.001 at 1 GHz.

51. The method according to claim 49 wherein said irradiating said COP surface comprises altering said COP surface to form carbonyl and hydroxyl group layer with thickness of 2 to 20 nm.

52. The method according to claim 49 wherein said treating said surface with an alkaline degreaser comprises cleaning the surface from any contaminants prior to said depositing said catalyst.

53. The method according to claim 49 wherein said depositing a catalyst layer comprises depositing Palladium (Pd) or Nickel (Ni) on said COP surface by immersion into an ionic metal solution to activate said surface for subsequent electroless plating.

54. The method according to claim 49 wherein said electrolessly plating a Ni—P seed layer on said catalyst comprises an autocatalytic process, wherein said Ni—P seed layer has a thickness of 0.1 μm+/−10% and a composition of Ni: 96.5˜97.5 wt % and P: 2.5˜3.5 wt %.

55. The method according to claim 49 wherein said plating said surface finishing comprises electrolytic Palladium, electrolytic Platinum, electrolytic Silver, electrolytic Titanium, electrolytic Tantalum, electrolytic Tungsten, immersion Tin, Electroless Palladium/Autocatalytic Gold (EPAG), or Immersion Gold/Electroless Palladium/Immersion Gold (IGEPIG).

56. The method according to claim 49 wherein said biocompatible flexible substrate is used in one of the group containing: medical devices, medical patches, medical imaging/diagnosis devices, implantable biomedical devices, and lab-on-flex.
